(19) United States
(12) Patent Application Publication
(10) Pub. No.: US 2014/0319562 A1
(43) Pub. Date: Oct. 30, 2014

(54) LIGHT-EMITTING DIODE PACKAGE STRUCTURE

(71) Applicants: Yun-Li Li, Tainan City (TW); Po-Jen Su, Tainan City (TW)

(72) Inventors: Yun-Li Li, Tainan City (TW); Po-Jen Su, Tainan City (TW)

(73) Assignee: GENESIS PHOTONICS INC., Tainan City (TW)

(21) Appl. No.: 14/096,009

(22) Filed: Dec. 4, 2013

(30) Foreign Application Priority Data
Apr. 29, 2013 (TW) 102115289

(51) Int. Cl. H01L 33/52; H01L 33/60; H01L 33/50

(52) U.S. Cl. CPC H01L 33/52; H01L 33/50; H01L 33/60
USPC 257/98; 257/100

(57) ABSTRACT

An LED package structure of the invention includes a light-emitting device and a transparent molding compound. The light-emitting device has an upper surface. The transparent molding compound is disposed on the light-emitting device and covers the upper surface, in which the transparent molding compound has a top surface and a bottom surface opposite to each other and a first outside surface connecting the top surface and the bottom surface. A surface area of the first outside surface is greater than or equal to four times of a horizontal projection area of the upper surface.

### CROSS-REFERENCE TO RELATED APPLICATION

This application claims the priority benefit of Taiwan application serial no. 102115289, filed on Apr. 29, 2013. The entirety of the above-mentioned patent application is hereby incorporated by reference herein and made a part of this specification.

### BACKGROUND OF THE INVENTION

1. Field of the Invention

The invention generally relates to a semiconductor package structure, and more particularly, to a light-emitting diode package structure (LED package structure).

2. Description of Related Art

With the advances in optoelectronic technology, the LED technology used to replace the traditional incandescent bulbs and fluorescent lamps and serving as the new generation light source gradually gets mature. The LED has advantage of low power consumption, small size, non-thermal luminescence and environmental protection, so that its application areas are gradually extended.

The LED light source is a directional light source, wherein the directly emitting region of light at the front of the LED light source usually has higher luminance, which makes the LED light source easily produce a glare problem. Generally, in an LED package structure, the package molding compound covering an LED chip has a lens-like shape. However, such a lens-like package molding compound has a limited light exiting angle, so that it is unable to have a larger light exiting angle to achieve the effect as a planar light source.

### SUMMARY OF THE INVENTION

Accordingly, the invention is directed to an LED package structure with larger lateral light exiting intensity.

An LED package structure of the invention includes a light-emitting device and a transparent molding compound. The light-emitting device has an upper surface. The transparent molding compound is disposed on the light-emitting device and covers the upper surface, in which the transparent molding compound has a top surface and a bottom surface opposite to each other and a first outside surface connecting the top surface and the bottom surface. The surface area of the first outside surface is greater than or equal to four times of the horizontal projection area of the upper surface.

In an embodiment of the invention, the surface area of the top surface of the transparent molding compound is equal to the horizontal projection area of the upper surface.

In an embodiment of the invention, the light-emitting device has a second outside surface and the second outside surface is coplanar to the first outside surface.

In an embodiment of the invention, the transparent molding compound entirely covers the upper surface of the light-emitting device.

In an embodiment of the invention, the light-emitting device includes a carrier and at least one LED chip. The carrier has a recess, and the LED chip is disposed in the recess and electrically connected to the carrier.

In an embodiment of the invention, the light-emitting device includes a substrate and at least one LED chip. The LED chip flips on the substrate and is electrically connected to the substrate, in which the LED chip has a light exiting surface and the light exiting surface faces the bottom surface of the transparent molding compound.

In an embodiment of the invention, the light-emitting device further includes a wavelength converting structure and the wavelength converting structure covers the LED chip.

In an embodiment of the invention, the transparent molding compound includes a first molding portion and a second molding portion, the first molding portion is located between the second molding portion and the light-emitting device, and a refractive index of the first molding portion is greater than a refractive index of the second molding portion.

In an embodiment of the invention, the LED package structure further includes a reflective layer with a reflectivity greater than 90%, in which the reflective layer is disposed on the top surface of the transparent molding compound.

The invention also provides an LED package structure, which includes a light-emitting device and a transparent molding compound. The light-emitting device has an upper surface. The transparent molding compound is disposed on the light-emitting device and covers the upper surface, in which the transparent molding compound has a top surface and a bottom surface opposite to each other and a first outside surface connecting the top surface and the bottom surface. The light-emitting device has a second outside surface and the second outside surface is coplanar to the first outside surface, and the maximum vertical distance between the top surface and the bottom surface of the transparent molding compound is greater than the maximum thickness of the light-emitting device.

In an embodiment of the invention, the surface area of the top surface of the transparent molding compound is equal to the horizontal projection area of the upper surface.

The invention further provides an LED package structure, which includes a light-emitting device and a transparent molding compound. The light-emitting device has an upper surface. The transparent molding compound is disposed on the light-emitting device and covers the upper surface, in which the transparent molding compound has a top surface and a bottom surface opposite to each other. The surface area of the top surface of the transparent molding compound is equal to a horizontal projection area of the upper surface, and the maximum vertical distance between the top surface and the bottom surface of the transparent molding compound is greater than the maximum thickness of the light-emitting device.

Based on the depiction above, since the surface area of the first outside surface of the transparent molding compound in the invention is greater than or equal to four times of the horizontal projection area of the upper surface of the light-emitting device or the maximum vertical distance between the top surface and the bottom surface of the transparent molding compound is greater than the maximum thickness of the light-emitting device, the side surface area of the transparent molding compound is thus increased. When the side surface area of the transparent molding compound is increased, the light flux exiting from the side surface is accordingly advanced. In addition, since the proportion of the surface area of the first outside surface of the transparent molding compound versus the horizontal projection area of the upper surface of the light-emitting device is greater than or equal to four times by design, the light emitted from the light-emitting device can be dispersed to the side surface of the transparent molding compound, then the light emits via the side surface of the transparent molding compound. As a result, the LED package structure of the invention has larger lateral light exiting intensity and better light uniformity and can achieve the effect as a planar light source.

In order to make the features and advantages of the present invention more comprehensible, the present invention is further described in detail in the following with reference to the embodiments and the accompanying drawings.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the invention.

FIG. 1A is a cross-sectional diagram of an LED package structure according to an embodiment of the invention.

FIG. 1B is a cross-sectional diagram of an LED package structure according to another embodiment of the invention.

FIG. 1C is a cross-sectional diagram of an LED package structure according to yet another embodiment of the invention.

FIG. 2 is a cross-sectional diagram of an LED package structure according to yet another embodiment of the invention.

FIG. 3 is a cross-sectional diagram of an LED package structure according to yet another embodiment of the invention.

FIG. 4 is a cross-sectional diagram of an LED package structure according to yet another embodiment of the invention.

FIG. 5 is a cross-sectional diagram of an LED package structure according to yet another embodiment of the invention.

FIG. 6 is a cross-sectional diagram of an LED package structure according to yet another embodiment of the invention.

### DESCRIPTION OF THE EMBODIMENTS

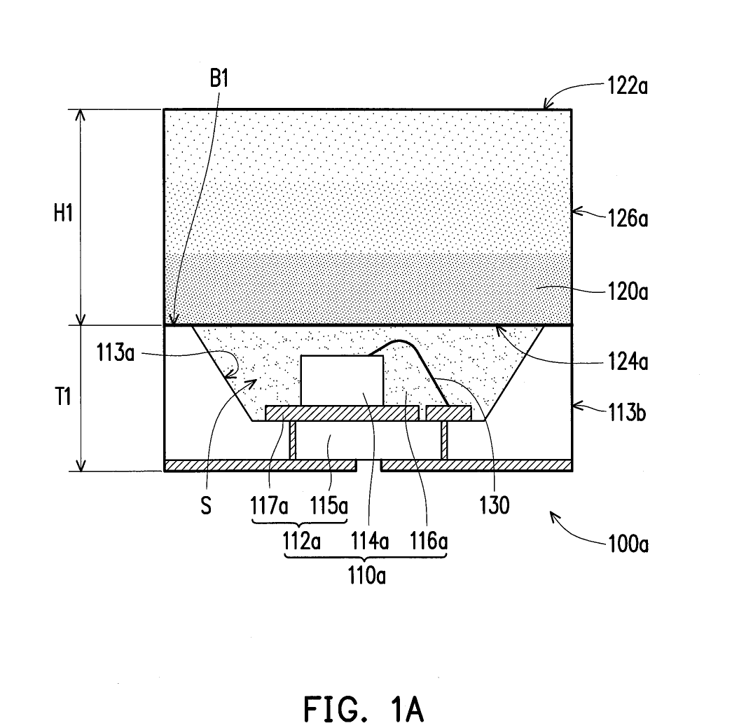

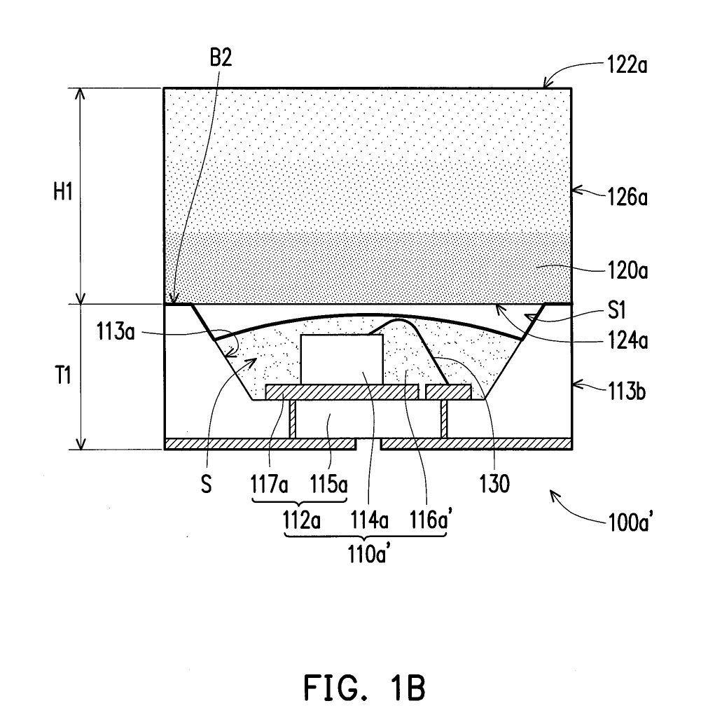

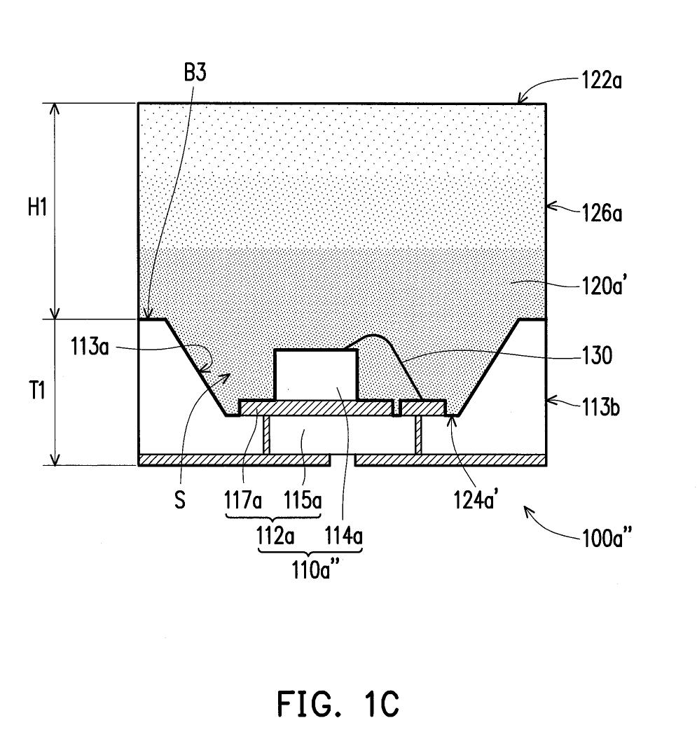

FIG. 1A is a cross-sectional diagram of an LED package structure according to an embodiment of the invention. Referring to FIG. 1A, in the embodiment, a LED package structure 100a includes a light-emitting device 110a and a transparent molding compound 120a. The light-emitting device 110a has an upper surface B1. The transparent molding compound 120a is disposed on the light-emitting device 110a and covers the upper surface B1. The transparent molding compound 120a has a top surface 122a and a bottom surface 124a opposite to each other and a first outside surface 126a connecting the top surface 122a and the bottom surface 124a. Specifically, a surface area of the first outside surface 126a of the transparent molding compound 120a is greater than or equal to four times of a horizontal projection area of the upper surface B1.

In more details, in the embodiment, the light-emitting device 110a includes a carrier 112a, at least one LED chip 114a (only one is shown in FIG. 1A) and a sealing adhesive 116a. The carrier 112a has a recess 113a and a second outside surface 113b, in which the transparent molding compound 120a and the carrier 112a together define a sealed space S. The LED chip 114a is disposed in the recess 113a and located in the sealed space S. The LED chip 114a is electrically connected to the carrier 112a. The sealing adhesive 116a is disposed in the sealed space S and covers the LED chip 114a, and the sealed space S is filled with the sealing adhesive 116a as shown in FIG. 1A. Further, the carrier 112a herein can comprise, for example, a casing 115a and a circuit layer 117a disposed on the casing 115a. The LED package structure 100a in the embodiment further includes at least one soldering line 130, and the LED chip 114a is electrically connected to the circuit layer 117a of the carrier 112a through the soldering line 130. In other unshown embodiments, the carrier can do comprise a leadframe and a casing connecting the leadframe, which still belongs to the scheme adopted by the invention without departing from the protection scope of the invention.

As shown in FIG. 1A, the transparent molding compound 120a of the embodiment entirely covers the upper surface B1 of the light-emitting device 110a. The surface area of the top surface 122a of the transparent molding compound 120a is equal to the horizontal projection area of the upper surface B1. The maximum vertical distance H1 between the top surface 122a and the bottom surface 124a of the transparent molding compound 120a is greater than the maximum thickness T1 of the light-emitting device 110a. The first outside surface 126a is substantially coplanar to the second outside surface 113b, i.e., the LED package structure 100a in the embodiment can be a cuboid or a cube, which the invention is not limited to. The carrier 112a of the light-emitting device 110a in the embodiment and the sealing adhesive 116a directly contact the partial bottom surface 124a of the transparent molding compound 120a so as to define the upper surface B1. The upper surface B1 is a horizontal surface and the transparent molding compound 120a entirely and directly covers the upper surface B1 as shown in FIG. 1A. When the upper surface B1 is a horizontal surface, the horizontal projection area of the upper surface B1 is equal to the area of the upper surface B1. In addition, the refractive index of the transparent molding compound 120a in the embodiment is, for example, between 1.1 and 1.7; preferably, the refractive index of the transparent molding compound 120a gradually decreases toward the top surface 122a from the bottom surface 124a. The material of the transparent molding compound 120a herein is, for example, silicone, epoxy resin or UV-cured colloid.

Since the surface area of the first outside surface 126a of the transparent molding compound 120a is greater than or equal to four times of the horizontal projection area of the upper surface B1 by design in the embodiment, the side surface area of the transparent molding compound 120a is increased, which thus advances the light flux exiting from the side surface of the transparent molding compound 120a. Moreover, since the proportion of the surface area of the first outside surface 126a of the transparent molding compound 120a versus the horizontal projection area of the upper surface B1 of the light-emitting device 110a is greater than or equal to four times by design, the light emitted from the light-emitting device 110a can be dispersed to the side surface of the transparent molding compound 120a (i.e., the first outside surface 126a), then the light emits though the side surface of the transparent molding compound 120a. In this way, the LED package structure 100a of the embodiment has larger lateral light exiting intensity and better light uniformity and can achieve the effect as a planar light source.

It should be noted that the notations and partial content in the above-mentioned embodiment are continuously used, in which the same notations represent the same as or similar to the above-mentioned embodiment, while the same depictions are omitted and can be understood referring to the above-mentioned embodiment, which is omitted in the following embodiments.

FIG. 1B is a cross-sectional diagram of an LED package structure according to another embodiment of the invention. Referring to FIG. 1B, the major difference of a LED package structure 100a′ in the embodiment from the LED package structure 100a of FIG. 1A is that the sealed space S is not fully filled with the sealing adhesive 116a′. The upper surface B2 of the light-emitting device 110a′ in the embodiment is not a horizontal surface, as shown in FIG. 1B, and the transparent molding compound 120a entirely covers the upper surface B2, but the partial region of the transparent molding compound 120a does not directly contact the upper surface B2 and there is air or without air in the contactless region S1.

FIG. 1C is a cross-sectional diagram of an LED package structure according to yet another embodiment of the invention. Referring to FIG. 1C, the major difference of a LED package structure 100a″ in the embodiment from the LED package structure 100a of FIG. 1A is that the light-emitting device 110a″ of the embodiment has no sealing adhesive 116a′ disposed, and the sealed space S is filled with the extending transparent molding compound 120a′ and the transparent molding compound 120a′ further covers the LED chip 114a, the circuit layer 117a and the soldering line 130, which means the bottom surface 124a′ of the transparent molding compound 120a′ directly contacts the casing 115a. At the time, the upper surface B3 of the light-emitting device 110a″ is the surface contacted by the transparent molding compound 120a′.

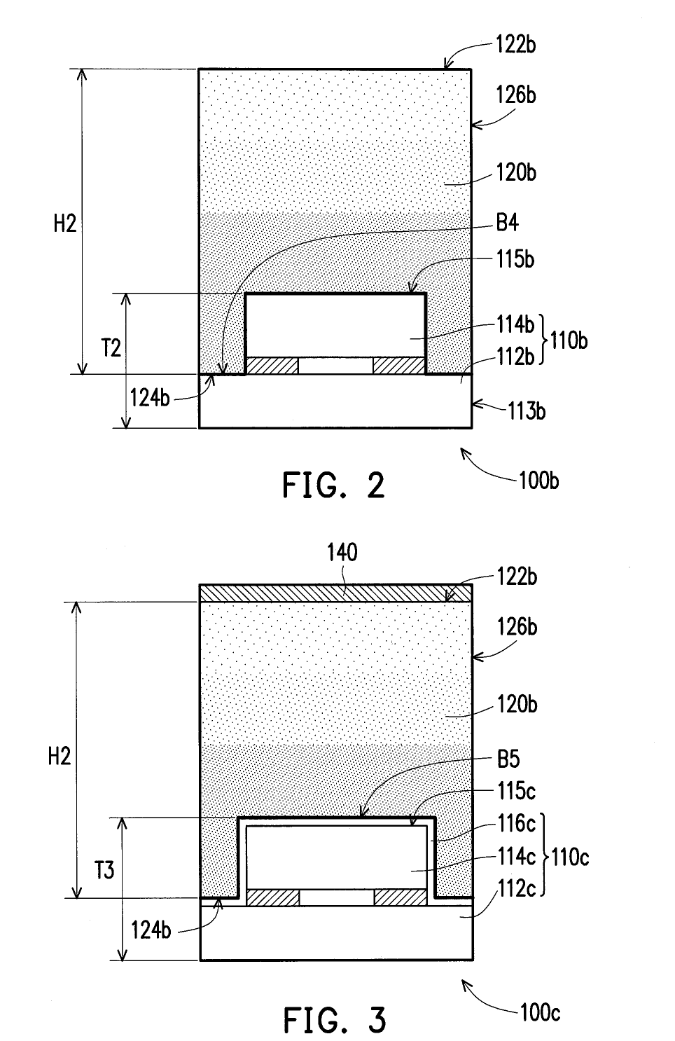

FIG. 2 is a cross-sectional diagram of an LED package structure according to yet another embodiment of the invention. Referring to FIG. 2, the major difference of a LED package structure 100b in the embodiment from the LED package structure 100a of FIG. 1A is that the light-emitting device 110b in the embodiment is different from the light-emitting device 110a of the above-mentioned embodiment. In more details, the light-emitting device 110b of the embodiment includes a substrate 112b and an LED chip 114b. The substrate 112b has a second outside surface 113b, and the LED chip 114b flips on the substrate 112b and is electrically connected to the substrate 112b. At the time, the LED chip 114b is electrically connected to the substrate 112b in flip-chip bonding method. The LED chip 114b has a light exiting surface 115b, in which the light exiting surface 115b faces the bottom surface 124b of the transparent molding compound 120b, and the upper surface B4 of the light-emitting device 110b is just the surface directly contacted by the transparent molding compound 120b and the LED chip 114b is, for example, a blue LED chip.

Since the surface area of the first outside surface 126b of the transparent molding compound 120b is greater than or equal to four times of the horizontal projection area of the upper surface B4 in the embodiment and the maximum vertical distance H2 between the top surface 122b and the bottom surface 124b of the transparent molding compound 120b is greater than the maximum thickness T2 of the light-emitting device 110b, the light emitted from the LED chip 114b is incident to the transparent molding compound 120b from the light exiting surface 115b, the maximum vertical distance H2 of the transparent molding compound 120b would affect the lateral light exiting efficiency. For example, the longer the maximum vertical distance H2 of the transparent molding compound 120b, the stronger the lateral light exiting efficiency of the LED package structure 100b is, which further makes the whole LED package structure 100b have larger lateral light exiting intensity and better light uniformity.

FIG. 3 is a cross-sectional diagram of an LED package structure according to yet another embodiment of the invention. Referring to FIG. 3, the major difference of a LED package structure 100c in the embodiment from the LED package structure 100b of FIG. 2 is that the LED package structure 100c in the embodiment further includes a reflective layer 140, in which the reflective layer 140 is disposed on the top surface 122b of the transparent molding compound 120b, and the reflectivity of the reflective layer 140 is greater than 90% and the material of the reflective layer 140 is, for example, silver or aluminium.

In addition, the light-emitting device 110c of the embodiment can optionally include a wavelength converting structure 116c. The wavelength converting structure 116c covers the LED chip 114c and the substrate 112c. Therefore, the light produced by the LED chip 114c (for example, blue light) can be converted into light in different colors (such as green, yellow or red light) by the wavelength converting structure 116c. After that, the light in different colors is mixed to produce white light. The wavelength converting structure 116c directly contacts the transparent molding compound 120b as shown in FIG. 3, and the surface where the wavelength converting structure 116c contacts the transparent molding compound 120b is the upper surface B5.

Since the surface area of the first outside surface 126b of the transparent molding compound 120b is greater than or equal to four times of the horizontal projection area of the upper surface B5 in the embodiment and the maximum vertical distance H2 between the top surface 122b and the bottom surface 124b of the transparent molding compound 120b is greater than the maximum thickness T3 of the light-emitting device 110c, and the reflective layer 140 is disposed on the top surface 122b of the transparent molding compound 120b, when the light emitted from the LED chip 114c is incident to the transparent molding compound 120b from the light exiting surface 115c, the light towards the top surface 122b will return back to the transparent molding compound 120b by the reflection of the reflective layer 140, followed by penetrating the first outside surface 126b for emitting out. In this way, the lateral light exiting efficiency of the LED package structure 100c is effectively increased.

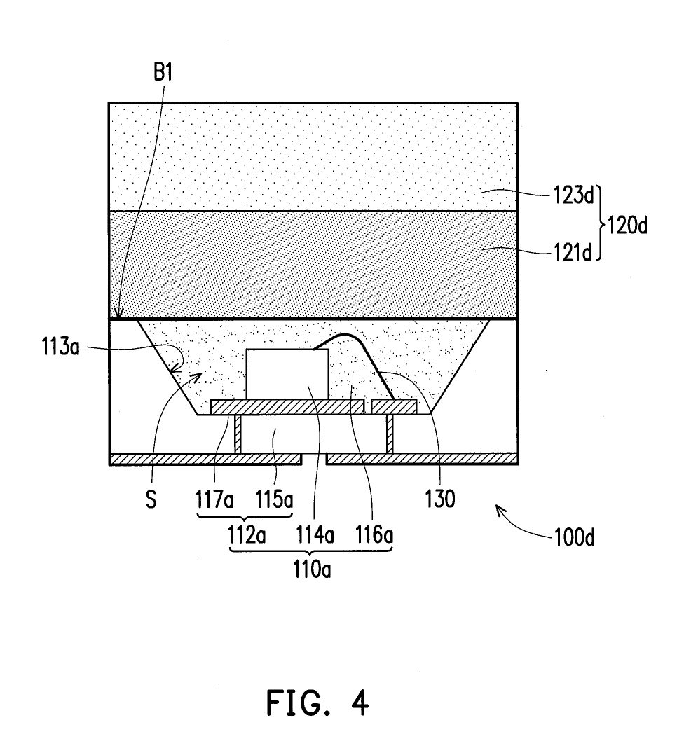

FIG. 4 is a cross-sectional diagram of an LED package structure according to yet another embodiment of the invention. Referring to FIG. 4, the major difference of a LED package structure 100d in the embodiment from the LED package structure 100b of FIG. 1A is that the transparent molding compound 120d of the LED package structure 100d in the embodiment further includes a first molding portion 121d and a second molding portion 123d. In more details, the first molding portion 121d is located between the second molding portion 123d and the light-emitting device 110a, while the light-emitting device 110a directly contacts a part of the first molding portion 121d. The refractive index of the first molding portion 121d is greater than the refractive index of the second molding portion 123d.

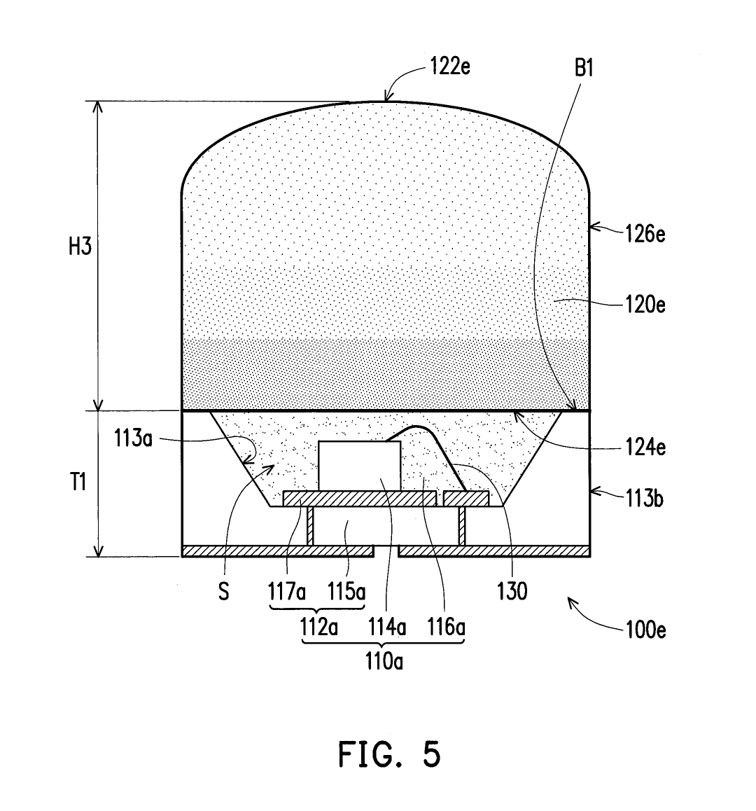

FIG. 5 is a cross-sectional diagram of an LED package structure according to yet another embodiment of the invention. Referring to FIG. 5, the major difference of a LED package structure 100e in the embodiment from the LED package structure 100a of FIG. 1A is the design of the transparent molding compound 120e. In more details, in the embodiment, the first outside surface 126e of the transparent molding compound 120e is substantially coplanar to the second outside surface 113b of the light-emitting device 110a, and the maximum vertical distance H3 between the top surface 122e and the bottom surface 124e of the transparent molding compound 120e is greater than the maximum thickness T1 of the light-emitting device 110a. The shape of the top surface 122e of the transparent molding compound 120e in the embodiment is embodied as quasi curved surface as shown by FIG. 5.

Since the first outside surface 126e of the transparent molding compound 120e is substantially coplanar to the second outside surface 113b of the light-emitting device 110a, and the maximum vertical distance H3 between the top surface 122e and the bottom surface 124e of the transparent molding compound 120e is greater than the maximum thickness T1 of the light-emitting device 110a, the LED package structure 100e of the embodiment has larger lateral light exiting intensity and better light uniformity. In other unshown embodiments, the technical stuff of the field can refer to the depiction in the above-mentioned embodiments to select the light-emitting device 110b mentioned in the above-mentioned embodiments to achieve the required technical effect, in which the LED chip 114b is electrically connected to the substrate 112b in flip-chip bonding method. However, the layout in the other embodiments still belongs to the scheme adopted by the invention and does not depart from the protection scope of the invention.

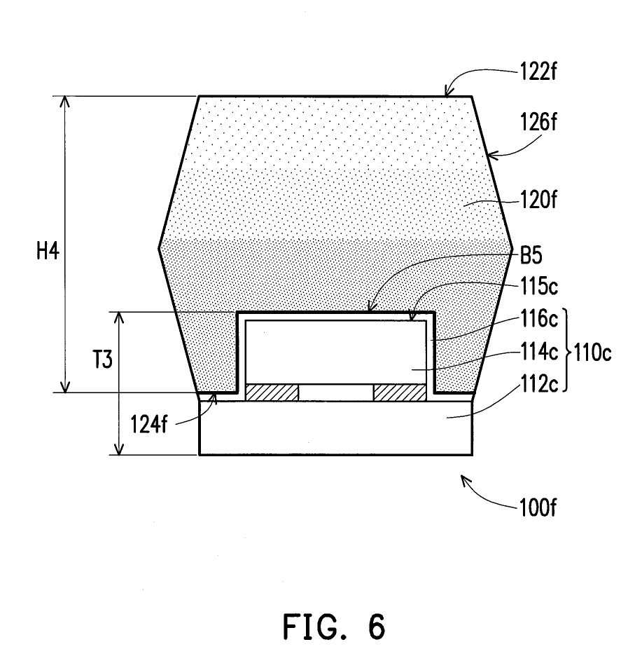

FIG. 6 is a cross-sectional diagram of an LED package structure according to yet another embodiment of the invention. Referring to FIG. 6, the major difference of a LED package structure 100f in the embodiment from the LED package structure 100c of FIG. 3 is that the LED package structure 100f in the embodiment further has no reflective layer 140 disposed therein and the design of the transparent molding compound 120f of the embodiment is different from the design of the transparent molding compound 120b. In more details, the surface area of the top surface 122f of the transparent molding compound 120f is equal to the horizontal projection area of the upper surface B5 in the embodiment, and the maximum vertical distance H4 between the top surface 122f and the bottom surface 124f of the transparent molding compound 120f is greater than the maximum thickness T3 of the light-emitting device 110c. The section shape of the transparent molding compound 120f in the embodiment is embodied as quasi hexagon.

Since the surface area of the top surface 122f of the transparent molding compound 120f is equal to the horizontal projection area of the upper surface B5 in the embodiment and the maximum vertical distance H4 between the top surface 122f and the bottom surface 124f of the transparent molding compound 120f is greater than the maximum thickness T3 of the light-emitting device 110c, when the light emitted from the LED chip 114c is incident to the transparent molding compound 120f from the light exiting surface 115c, the lateral light exiting from the LED package structure 100f gets stronger, which makes the LED package structure 100f have larger lateral light exiting intensity and better light uniformity. In other unshown embodiments, the technical stuff of the field can refer to the depiction of the above-mentioned embodiments to select the light-emitting device 110a mentioned in the above-mentioned embodiments to achieve the required technical effect, in which the LED chip 114a is electrically connected to the substrate 112a in wire bonding method through the soldering line 130. However, the layout in the other embodiments still belongs to the scheme adopted by the invention and does not depart from the protection scope of the invention.

In summary, since the surface area of the first outside surface of the transparent molding compound in the invention is greater than or equal to four times of the horizontal projection area of the upper surface of the light-emitting device or the maximum vertical distance between the top surface and the bottom surface of the transparent molding compound is greater than the maximum thickness of the light-emitting device, the side surface area of the transparent molding compound is thus increased. When the side surface area of the transparent molding compound is increased, the light flux exiting from the side surface is accordingly advanced. In addition, since the proportion of the surface area of the first outside surface of the transparent molding compound versus the horizontal projection area of the upper surface of the light-emitting device is greater than or equal to four times by design, the light emitted from the light-emitting device can be dispersed to the side surface of the transparent molding compound, then the light emits via the side surface of the transparent molding compound. As a result, the LED package structure of the invention has larger lateral light exiting intensity and better light uniformity and can achieve the effect as a planar light source.

It will be apparent to those skilled in the art that the descriptions above are several preferred embodiments of the invention only, which does not limit the implementing range of the invention. Various modifications and variations can be made to the structure of the invention without departing from the scope or spirit of the invention. The claim scope of the invention is defined by the claims hereinafter.

What is claimed is:

1. A light-emitting diode package structure, comprising:
a light-emitting device, having an upper surface; and
a transparent molding compound, disposed on the light-emitting device and covering the upper surface, the transparent molding compound having a top surface and a bottom surface opposite to each other, and a first outside surface connecting the top surface and the bottom surface, wherein a surface area of the first outside surface is greater than or equal to four times of a horizontal projection area of the upper surface.

2. The light-emitting diode package structure as claimed in claim 1, wherein a surface area of the top surface of the transparent molding compound is equal to the horizontal projection area of the upper surface.

3. The light-emitting diode package structure as claimed in claim 1, wherein the light-emitting device has a second outside surface and the second outside surface is coplanar to the first outside surface.

4. The light-emitting diode package structure as claimed in claim 1, wherein the transparent molding compound entirely covers the upper surface of the light-emitting device.

5. The light-emitting diode package structure as claimed in claim 1, wherein the light-emitting device comprises:
a carrier, having a recess; and
at least one light-emitting diode chip, disposed in the recess and electrically connected to the carrier.

6. The light-emitting diode package structure as claimed in claim 1, wherein the light-emitting device comprises:
a substrate; and
at least one light-emitting diode chip, flipping on the substrate and electrically connected to the substrate, wherein the light-emitting diode chip has a light exiting surface and the light exiting surface faces the bottom surface of the transparent molding compound.

7. The light-emitting diode package structure as claimed in claim 5, wherein the light-emitting device further comprises a wavelength converting structure and the wavelength converting structure covers the light-emitting diode chip.

8. The light-emitting diode package structure as claimed in claim 6, wherein the light-emitting device further comprises a wavelength converting structure and the wavelength converting structure covers the light-emitting diode chip.

9. The light-emitting diode package structure as claimed in claim 1, wherein the transparent molding compound comprises a first molding portion and a second molding portion, the first molding portion is located between the second molding portion and the light-emitting device, and a refractive index of the first molding portion is greater than a refractive index of the second molding portion.

10. The light-emitting diode package structure as claimed in claim 1, further comprising a reflective layer with a reflectivity greater than 90%, wherein the reflective layer is disposed on the top surface of the transparent molding compound.

11. A light-emitting diode package structure, comprising:
a light-emitting device, having an upper surface; and
a transparent molding compound, disposed on the light-emitting device and covering the upper surface, the transparent molding compound having a top surface and a bottom surface opposite to each other, and a first outside surface connecting the top surface and the bottom surface, wherein the light-emitting device has a second outside surface and the second outside surface is coplanar to the first outside surface, and a maximum vertical distance between the top surface and the bottom surface of the transparent molding compound is greater than a maximum thickness of the light-emitting device.

12. The light-emitting diode package structure as claimed in claim 11, wherein a surface area of the top surface of the transparent molding compound is equal to a horizontal projection area of the upper surface.

13. A light-emitting diode package structure, comprising:
a light-emitting device, having an upper surface; and
a transparent molding compound, disposed on the light-emitting device and covering the upper surface, the transparent molding compound having a top surface and a bottom surface opposite to each other, wherein a surface area of the top surface of the transparent molding compound is equal to a horizontal projection area of the upper surface, and a maximum vertical distance between the top surface and the bottom surface of the transparent molding compound is greater than a maximum thickness of the light-emitting device.
